(19) United States
(12) Patent Application Publication
(10) Pub. No.: US 2005/0287792 A1
(43) Pub. Date: Dec. 29, 2005

(54) Method for forming barrier layer of semiconductor device

(75) Inventor: Shim Cheon Man, Seoul (KR)

Correspondence Address: THE LAW OFFICES OF ANDREW D. FORTNEY, PH.D., P.C., 7257 N. MAPLE AVENUE, BLDG. D, SUITE 107, FRESNO, CA, 93720, US

(73) Assignee: DongbuAnam Semiconductor Inc.

(21) Appl. No.: 11/166,678

(22) Filed: Jun. 23, 2005

(30) Foreign Application Priority Data
Jun. 24, 2004 (KR) 10-2004-0047589

(51) Int. Cl. H01L 21/4763

(52) U.S. Cl. 438/627

(57) ABSTRACT

A method for forming a barrier layer of a semiconductor device is disclosed, to improve the advantageous characteristics of device by obtaining the uniformity on depositing a barrier layer eve in case an etching profile is not in shape of the vertical, which includes the steps of loading a wafer having a line pattern layer for a metal line on a wafer stage of a deposition equipment; forming a diffusion barrier layer on the line pattern layer in state of rotating the wafer stage; and forming a seed metal layer, wherein the seed metal layer serves as a seed when forming a main line layer on the diffusion barrier layer.

### CROSS-REFERENCE TO RELATED APPLICATIONS

This application claims the benefit of Korean Application No. P2004-47589 filed on Jun. 24, 2004, which is hereby incorporated by reference as if fully set forth herein.

### BACKGROUND OF THE INVENTION

1. Field of the Invention

The present invention relates to a semiconductor device, and more particularly, to a method for forming a barrier layer of a semiconductor device, to improve the advantageous characteristics of device by obtaining the uniformity on depositing a barrier layer eve in case an etching profile is not in shape of the vertical.

2. Discussion of the Related Art

To form the wiring in the process of fabricating a semiconductor device, a conductive layer is deposited on an insulating layer of aluminum Al or tungsten W, and is then patterned by photolithography and dry-etching process. In case of a logic device requiring the high speed among the various semiconductor devices, a method for forming a line layer of a metal material having low resistivity has been actively researched and developed. For example, the line layer is formed of copper Cu having low resistivity, instead of aluminum Al or tungsten W.

In case of forming the line layer of copper Cu, the patterning process of the line layer of copper Cu is more difficult than the patterning process of the line layer of aluminum Al or tungsten W. Accordingly, the Line Damascene process is generally used for forming the line layer by burying a trench (the area for forming the line layer). Especially, the Dual Damascene process is usually performed, in which a via-hole connected with a lower conductive layer is formed in an insulating interlayer with a trench, and a line layer is formed in the via-hole and the trench.

In the process of forming the line layer of copper Cu by the Dual Damascene, copper Cu is easily diffused to the portion between the insulating interlayers, unlike aluminum Al or tungsten W. Accordingly, it is necessary to form a thin diffusion barrier layer of conductive material, so as to prevent the diffusion of copper Cu to the inside surface of the trench and the via-hole (that is, the inner side surface and the inner bottom surface).

Hereinafter, a method for forming a diffusion barrier layer in a semiconductor device according to the related art will be described with reference to the accompanying drawings.

FIG. 1A and FIG. 2B show the plasma incident angle according to the etching profile. FIG. 2A and FIG. 2B show the deposition form of diffusion barrier layer according to the etching profile.

In case of forming a metal line of copper Cu, the metal line of copper Cu has the low resistivity and the great electro-migration and stress-migration characteristics, as compared with a metal line of aluminum Al. Accordingly, it is possible to improve the reliability in chip of the semiconductor device.

The metal line of copper Cu requires the additional diffusion barrier layer due to the great diffusion characteristics of copper. Generally, the diffusion barrier layer is formed of TiN, TaN or ternary components.

In case of the metal line, it fundamentally has the structure of Cu, a seed layer, a dissusion layer and Si, in due consideration of the electric characteristics between each of the layers, the thermal stability, the crystal structure, and the interface reaction characteristics.

After forming a line pattern layer for the metal line, the diffusion barrier layer is then the seed metal layer is formed. In the etching process for formation of the line the etching profile may be ununiform according to the etching conditions.

If the etching profile is ununiform, it is difficult to deposit the barrier layer for the metal line of copper Cu.

FIG. 1A shows the plasma incident angle in case of the normal etching profile. FIG. 1B shows the plasma incident angle in case of the abnormal etching profile.

As shown in (4) of FIG. 1A, the angle (θ1) between the etching surface of line and the upper surface of wafer is less than 90°. As shown in (5) of FIG. 1B, the angle (θ2) between the etching surface of line pattern layer and the upper surface of wafer is more than 90°.

If the angle between the etching surface of line pattern layer and the upper surface of water is more than 90°, it is difficult to deposit the diffusion barrier layer.

In (1) of FIG. 1A, the plasma is incident to the surface at an angle of 90° on the plasma deposition process for forming the diffusion barrier layer.

In (2) and (3) of FIG. 1A, the plasma is incident to the surface at an acute angle the plasma deposition process for forming the diffusion barrier layer.

FIG. 2A shows the deposition state of the diffusion barrier layer when having the etching profile, as shown in FIG. 1A when the angle between the etching surface of line pattern upper surface of wafer is less than 90°. In this case, the diffusion barrier layer is uniformly deposited as shown in (6) of FIG. 2A.

FIG. 2B shows the deposition state of the diffusion barrier layer when having the etching profile, as show in FIG. 1B when the angle between the etching surface of line pattern layer and the upper surface of wafer is more than 90°. In this case, the diffusion barrier layer is ununiformly deposited as shown in (7) of FIG. 2B.

The etching profile of the line pattern layer has the great effects on the deposition of the diffusion barrier layer. Accordingly, the line pattern layer may include the portion having no diffusion barrier layer deposited thereon. In the portion having no diffusion barrier layer, the seed layer is also not deposited. As a result, even though the high-priced equipment is used, it is impossible to deposit copper Cu uniformly. Thus, in case the semiconductor device uses the metal line of copper, it may cause the dramatic decrease of yield.

### SUMMARY OF THE INVENTION

Accordingly, the present invention is directed to a method for forming a barrier layer of a semiconductor device that substantially obviate one or more problems due to limitations and disadvantages of the related art.

An object of the present invention is to provide a method for forming a barrier layer of a semiconductor device, to improve the advantageous characteristics of device by obtaining the uniformity on depositing a barrier layer eve in case an etching profile is not in shape of the vertical.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a method for forming a barrier layer of a semiconductor device includes the steps of loading a wafer having a line pattern layer for a metal line on a wafer stage of a deposition equipment; forming a diffusion barrier layer on the line pattern layer in state of rotating the wafer stage; and forming a seed metal layer, wherein the seed metal layer serves as a seed when forming a main line layer on the diffusion barrier layer.

At this time, a central axis of the wafer is corresponding to a rotation axis of the wafer stage when forming the diffusion barrier layer. Or, a central axis of the wafer is not corresponding to a rotation axis of the wafer stage when forming the diffusion barrier layer.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiments of the invention and together with the description serve to explain the principle of the invention. In the drawings:

FIG. 1A and FIG. 2B show the plasma incident angle according to the etching profile;

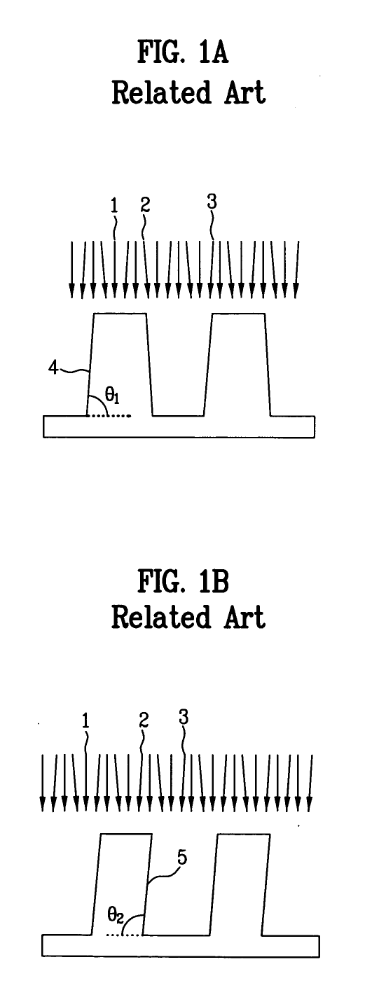

FIG. 2A and FIG. 2B show the deposition form of diffusion barrier layer according to the etching profile;

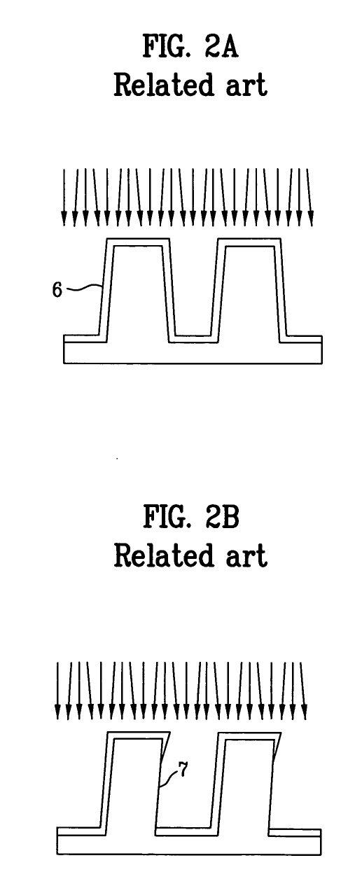

FIG. 3A and FIG. 3B shows the process for forming a diffusion barrier layer according to the present invention; and

FIG. 4 shows the deposition form of diffusion barrier layer according to the present invention.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

Hereinafter, a method for forming a diffusion barrier layer in a semiconductor device according to the present invention will be described with reference to the accompanying drawings.

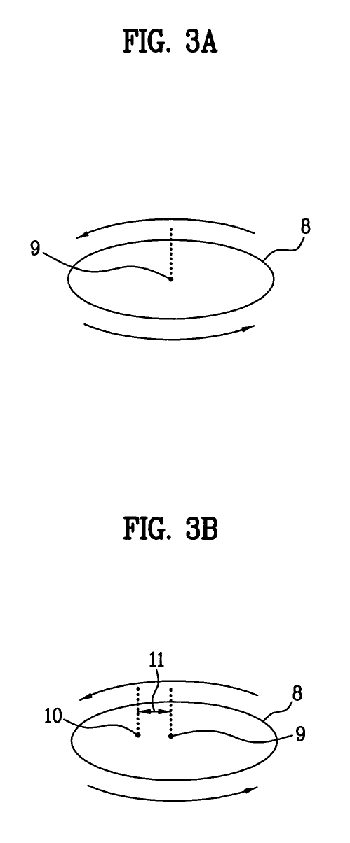

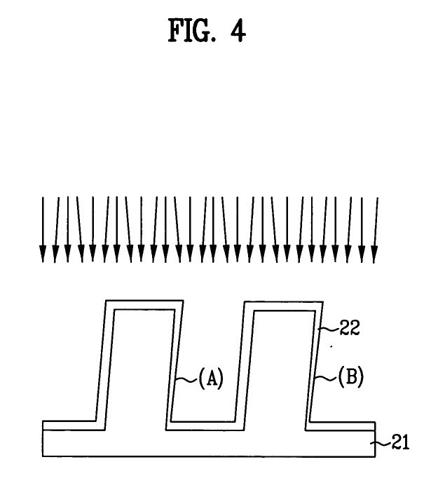

FIG. 3A and FIG. 3B shows the process for forming a diffusion barrier layer according to the present invention. FIG. 4 shows the deposition form of a diffusion barrier layer according to the present invention.

In the method for forming a diffusion barrier layer according to the present invention, even in case an etching profile of a line pattern layer is not in shape of the vertical, it is possible to obtain the uniformity in the diffusion barrier layer by rotating a wafer when depositing the diffusion barrier layer.

In FIG. 3A, the diffusion barrier layer is deposited in state of rotating the wafer 8 on a central axis 9, the wafer 8 having the etched line pattern layer. At this time, the central axis 9 corresponds to a rotation axis.

In case of FIG. 3B, the diffusion barrier layer is deposited in state of rotating the wafer 8 on a rotation axis 10, wherein the rotation axis 10 is formed at the predetermined interval 11 from a central axis 9. Accordingly, it is possible to improve the deposition efficiency in the predetermined portions wherein the etching profile of the line pattern layer is not in shape of the vertical, since the wafer 8 rotates on the rotation axis.

On the process for forming a copper line layer, the diffusion barrier layer is formed by PECVD (Plasma Enhanced Chemical Vapor Deposition), ALD (Atomic Layer Deposition) and HDP CVD (High Density Plasma CVD). To obtain the uniformity and step coverage characteristics, after the wafer is loaded in a chamber having a tightly sealed reaction area therein, and is then put on a wafer stage, various reaction materials are provided into the reaction area of the chamber, thereby forming the diffusion barrier layer of the desired thickness.

In the present invention, after the wafer is loaded in the chamber, and is put on the wafer stage, the diffusion barrier layer is formed in state of rotating the wafer stage.

In the ALD process for forming the diffusion barrier layer, the thin film grows as atomic layer by the surface reaction. Also, the thickness of thin film deposited is determined according to the number of cycle. Thus, it is very easy to control the thickness of diffusion barrier layer. In a large-sized substrate, the ALD process has the greater uniformity in thickness of the diffusion barrier layer as compared with the CVD process. In this respect, the ALD process having the great realization is widely used.

The diffusion barrier layer may be formed by the other fabrication technology in due consideration of the deposition temperature, the thickness of thin film, and the impurity content of the formed thin film.

In the method for forming the diffusion barrier layer according to the present invention, the wafer is loaded on the wafer stage, and then the wafer stage is rotated to any one direction of the left and right sides, or to both the left and right directions, thereby improving the deposition efficiency.

The diffusion barrier layer may be formed of TiN, TaN, or ternary components.

FIG. 4 shows the process of forming the diffusion barrier layer of the semiconductor device according to the present invention. As shown in FIG. 4, the diffusion barrier layer 22 is uniformly deposited without regard to the etching profile of the line pattern layer 21. That is, the diffusion barrier layer 22 is uniformly formed in the predetermined portions of (A) and (B) wherein the etching profile is not in shape of the vertical.

The deposition method according to the present invention is not limited to the diffusion barrier layer. That is, the deposition method according to the present invention may be applicable to the process for forming the other material layers.

As mentioned above, the method for forming the diffusion barrier layer of the semiconductor device according to the present invention has the following advantages.

First, the diffusion barrier layer is uniformly deposited on the all portions without regard to the etching profile of the line pattern layer for the metal line. Accordingly, it is possible to obtain the uniform deposition of a seed layer for forming a main line layer, thereby improving the electric characteristics in the device. Thus, it is possible to improve the yield.

Also, the deposition process of the diffusion barrier layer is performed in state of rotating the wafer. Accordingly, it is possible to provide the sufficient margin for controlling plasma stream, and to decrease the production cost of the device without the high-priced equipments.

The diffusion barrier layer is uniformly deposited without regard to the etching profile of the line pattern layer for forming the metal line, so that it is possible to obtain the sufficient margin for forming the line pattern layer during the etching process.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

1. A method for forming a barrier layer of a semiconductor device comprising:
loading a wafer having a line pattern layer for a metal line on a wafer stage of a deposition equipment;
forming a diffusion barrier layer on the line pattern layer in state of rotating the wafer stage; and
forming a seed metal layer, wherein the seed metal layer serves as a seed when forming a main line layer on the diffusion barrier layer.

2. The method of claim 1, wherein a central axis of the wafer is corresponding to a rotation axis of the wafer stage when forming the diffusion barrier layer.

3. The method of claim 1, wherein a central axis of the wafer is not corresponding to a rotation axis of the wafer stage when forming the diffusion barrier layer.

4. The method of claim 1, wherein the wafer is rotated to any one direction of the left and right sides, or to both the left and right sides.
